(19) United States
(12) Patent Application Publication
(10) Pub. No.: US 2009/0203218 A1
(43) Pub. Date: Aug. 13, 2009

(54) PLASMA ETCHING METHOD AND COMPUTER-READABLE STORAGE MEDIUM

(75) Inventors: Shoichiro Matsuyama, Nirasaki City (JP); Masanobu Honda, Nirasaki City (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/369,199

(22) Filed: Feb. 11, 2009

Related U.S. Application Data
(60) Provisional application No. 61/048,241, filed on Apr. 28, 2008.

(30) Foreign Application Priority Data
Feb. 12, 2008 (JP) 2008-030078

(51) Int. Cl. H01L 21/3065

(52) U.S. Cl. 438/719; 257/E21.218

(57) ABSTRACT

A plasma etching method includes etching an etching target layer formed on a substrate to be processed by a plasma of a processing gas by using an ArF photoresist as a mask. The etching target layer is a silicon nitride layer or silicon oxide layer, and the processing gas contains at least a CF₃I gas. A high frequency power having a frequency of 13.56 MHz or less is applied to a lower electrode mounting the substrate thereon.

### FIELD OF THE INVENTION

The present invention relates to a plasma etching method for etching an etching target layer formed on a substrate to be processed by a plasma of a processing gas by using an ArF photoresist as a mask and a computer-readable storage medium.

### BACKGROUND OF THE INVENTION

Conventionally, in a manufacturing process of a semiconductor device, plasma etching is widely performed to etch an etching target layer such as a silicon nitride layer and a silicon oxide layer formed on a substrate to be processed by a plasma of a processing gas by using a photoresist as a mask.

Further, in plasma etching, an ArF photoresist is replacing a conventional KrF photoresist to meet a demand for miniaturization of a circuit pattern in a recent semiconductor device. However, the ArF photoresist has a lower plasma resistance than the KrF photoresist and surface roughness occurs. Accordingly, for example, a technique for suppressing surface roughness of the ArF photoresist is disclosed in Japanese Patent Laid-open Application No. 2006-32721. In this technique, when a contact hole is formed through an ArF photoresist, plasma etching is performed on an antireflection layer at a gas pressure of 6.66 Pa (50 mTorr) by using a processing gas of CF₄, CHF₃, CF₃I or the like, thereby suppressing surface roughness of the ArF photoresist.

As described above, since the ArF photoresist has a low plasma resistance, conventionally, plasma etching is performed at a low gas pressure to thereby form a contact hole.

Further, as a result of a detailed investigation, the inventors of the present invention have found out that when a pattern having lines and spaces was formed on an etching target layer such as a silicon nitride layer and a silicon oxide layer through an ArF photoresist, striation, line edge roughness (LER) (wave of line edge (one side)), line width roughness (LWR) (variation in line width) or the like was generated after etching due to roughness of the surface and sidewall of the ArF photoresist having a low plasma resistance. Further, in plasma etching, preferably, anisotropic plasma etching is performed by applying a bias voltage having a relatively low frequency of 13.56 MHz or less for accelerating ions to a lower electrode on which a substrate is mounted. However, when a high bias voltage was applied, it was investigated that roughness of the surface and sidewall of the ArF photoresist increased and large striation, LER, LWR or the like was generated.

### SUMMARY OF THE INVENTION

In view of the above, the present invention provides a plasma etching method capable of suppressing roughness of a surface and sidewall of the ArF photoresist in highly anisotropic plasma etching having application of a high bias voltage and capable of forming a desired pattern with good precision by suppressing generation of striation, LER and LWR, and a computer-readable storage medium.

In accordance with an embodiment of the present invention, there is provided a plasma etching method comprising: etching an etching target layer formed on a substrate to be processed by a plasma of a processing gas by using an ArF photoresist as a mask, wherein the etching target layer is a silicon nitride layer or silicon oxide layer, the processing gas contains at least a CF₃I gas, and a high frequency power having a frequency of 13.56 MHz or less is applied to a lower electrode mounting the substrate thereon.

In the plasma etching method, the high frequency power, having a frequency of 13.56 MHz or less and applied to the lower electrode, may be equal to or larger than 500 W.

In the plasma etching method, an etching pattern having lines and spaces may be formed on the etching target layer, and the etching pattern may include a dense pattern portion in which a ratio of a line width to a space width is 1/1 (line width/space width) and a sparse pattern portion in which a ratio of a line width to a space width is 1/10 or less.

In the plasma etching method, a second high frequency power having a frequency of 27 MHz or more in addition to the high frequency power having a frequency of 13.56 MHz or less may be applied to the lower electrode.

In accordance with the embodiment of the present invention, it is possible to provide a plasma etching method capable of suppressing roughness of a surface and sidewall of the ArF photoresist in highly anisotropic plasma etching having application of a high bias voltage and capable of forming a desired pattern with good precision by suppressing generation of striation, LER and LWR, and a computer-readable storage medium.

### BRIEF DESCRIPTION OF THE DRAWINGS

The objects and features of the present invention will become apparent from the following description of embodiments given in conjunction with the accompanying drawings, in which:

FIG. 1 is an enlarged view showing a cross sectional configuration of a semiconductor wafer in a plasma etching method in accordance with an embodiment of the present invention;

FIG. 2 illustrates a schematic configuration of a plasma etching apparatus in accordance with the embodiment of the present invention;

FIG. 3 shows a relationship between an etching rate (in a dense pattern portion) and a bias power in the experimental example and comparison example;

FIG. 4 shows a relationship between an etching rate (in a sparse pattern portion) and a bias power in the experimental example and comparison example;

FIG. 5 shows a relationship between selectivity (in dense and sparse pattern portions) and a bias power in the experimental example and comparison example;

FIG. 6 illustrates SEM photographs showing a relationship between a bias power and an ArF resist state in the experimental example and comparison example;

FIG. 7 shows a bar graph showing LWR in a low frequency (long wavelength) range; and

FIG. 8 shows a bar graph showing LWR in a high frequency (short wavelength) range.

### DETAILED DESCRIPTION OF THE EMBODIMENTS

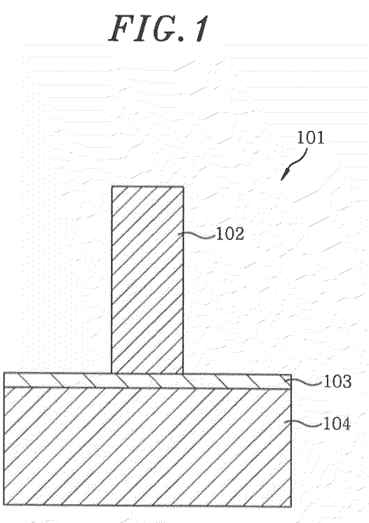

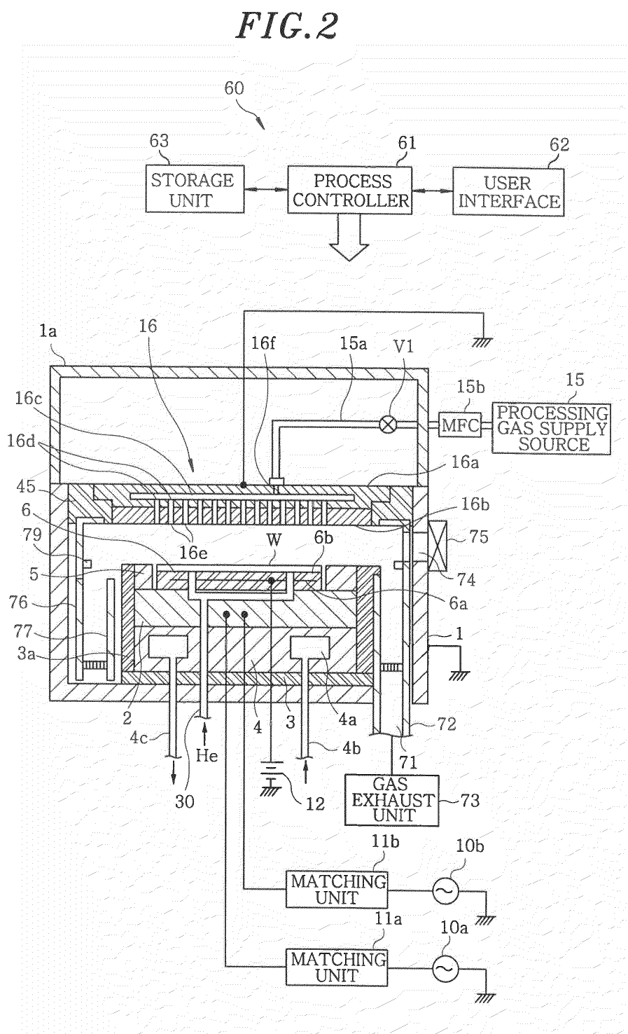

Hereinafter, embodiments of the present invention will be described in detail with reference to the accompanying drawings which form a part hereof. FIG. 1 is an enlarged view showing a cross sectional configuration of a semiconductor wafer serving as a substrate to be processed in a plasma etching method in accordance with an embodiment of the present invention. FIG. 2 illustrates a configuration of a plasma etching apparatus in accordance with the embodiment of the present invention. First, the configuration of the plasma etching apparatus will be described with reference to FIG. 2.

The plasma etching apparatus includes a processing chamber 1 which is airtightly sealed and electrically connected to a ground potential. The processing chamber 1 has a cylindrical shape and is made of, e.g., aluminum. A mounting table 2 is provided in the processing chamber 1 to horizontally support the semiconductor wafer W serving as a substrate to be processed. The mounting table 2 is made of, e.g., aluminum and is supported by a support base 4 of a conductor through an insulating plate 3. A focus ring 5 made of, e.g., single crystalline silicon is provided at an upper periphery of the mounting table 2. Further, a cylindrical inner wall member 3a made of, e.g., quartz is provided to surround the support base 4 of the mounting table 2.

The mounting table 2 is connected to a first RF power supply 10a via a first matching unit 11a and also connected to a second RF power supply 10b via a second matching unit 11b. The second RF power supply 10b for generating a plasma supplies a high frequency power having a specific frequency (27 MHz or more, e.g., 40 MHz) to the mounting table 2. Further, the first RF power supply 10a for attracting ions supplies a high frequency power having a specific frequency (13.56 MHz or less, e.g., 13.56 MHz) lower than that of the second RF power supply 10b to the mounting table 2. Meanwhile, a shower head 16 connected to a ground potential is provided above the mounting table 2 to face the mounting table 2 in parallel. The mounting table 2 and the shower head 16 serve as a pair of electrodes.

An electrostatic chuck 6 for electrostatic adsorption of the semiconductor wafer W is provided on an upper surface of the mounting table 2. The electrostatic chuck 6 is configured by embedding an electrode 6a in an insulator 6b. The electrode 6a is connected to a DC power supply 12. Accordingly, when a DC voltage is applied to the electrode 6a from the DC power supply 12, the semiconductor wafer W is adsorbed to the electrostatic chuck 6 by a Coulomb force.

A coolant path 4a is formed in the support base 4. The coolant path 4a is connected to a coolant inlet line 4b and a coolant outlet line 4c. The support base 4 and the mounting table 2 can be controlled to have a predetermined temperature by circulating an appropriate coolant, e.g., cooling water in the coolant path 4a. Further, a backside gas supply line 30 for supplying a cold heat transfer gas (backside gas) such as a helium gas to a backside of the semiconductor wafer W is formed to pass through the mounting table 2 and the like. The backside gas supply line 30 is connected to a backside gas supply source (not shown). By providing this configuration, the semiconductor wafer W, which is adsorptively held on the upper surface of the mounting table 2 by the electrostatic chuck 6, can be controlled to be maintained at a predetermined temperature.

The shower head 16 is provided at a ceiling wall of the processing chamber 1. The shower head 16 includes a main body portion 16a and an upper ceiling plate 16b forming an electrode plate. The shower head 16 is supported by a support member 45 provided at an upper portion of the processing chamber 1. The main body portion 16a is made of a conductive material, e.g., anodically oxidized aluminum and is configured to detachably support the upper ceiling plate 16b provided under the main body portion 16a.

A gas diffusion space 16c is formed inside the main body portion 16a. Gas through holes 16d are formed at the bottom portion of the main body portion 16a to be positioned under the gas diffusion space 16c. Further, gas inlet holes 16e are formed in the upper ceiling plate 16b corresponding to the gas through holes 16d to pass through the upper ceiling plate 16b in its thickness direction. By providing this configuration, a processing gas supplied to the gas diffusion space 16c is supplied to be dispersed in a shower pattern into the processing chamber 1 via the gas through holes 16d and the gas inlet holes 16e. Further, a line (not shown) for circulating a coolant is provided at the main body portion 16a or the like so as to cool the shower head 16 to a desired temperature during a plasma etching process.

A gas inlet port 16f for introducing a processing gas into the gas diffusion space 16c is formed at the main body portion 16a. The gas inlet port 16f is connected to one end of a gas supply line 15a. The other end of the gas supply line 15a is connected to a processing gas supply source 15 for supplying a processing gas for etching (etching gas). Further, the gas supply line 15a is provided with a mass flow controller (MFC) 15b and a valve V1 sequentially from its upstream side. Further, a gas containing at least a CF₃I gas, serving as a processing gas for plasma etching, is supplied to the gas diffusion space 16c from the processing gas supply source 15 through the gas supply line 15a. The gas is supplied to be dispersed in a shower pattern into the processing chamber 1 from the gas diffusion space 16c through the gas through holes 16d and the gas inlet holes 16e.

A cylindrical ground conductor 1a is provided at a higher position than a vertical position of the shower head 16 to extend upward from a sidewall of the processing chamber 1. The cylindrical ground conductor 1a has a ceiling wall at its upper portion.

A gas exhaust port 71 is formed at a bottom portion of the processing chamber 1. The gas exhaust port 71 is connected to a gas exhaust unit 73 via a gas exhaust pipe 72. The gas exhaust unit 73 has a vacuum pump which is operated such that the processing chamber 1 can be depressurized to a specific vacuum level. Meanwhile, a loading/unloading port 74 is provided at the sidewall of the processing chamber 1 such that the wafer W is loaded into or unloaded from the processing chamber 1 through the loading/unloading port 74. Further, a gate valve 75 for opening and closing the loading/unloading port 74 is provided at the loading/unloading port 74.

Reference numerals 76 and 77 of FIG. 2 designate detachable deposition shields. The deposition shield 76 is provided along an inner wall surface of the processing chamber 1. The deposition shield 76 prevents etching by-products (depositions) from being adhered to the processing chamber 1. A conductive member (GND block) 79, which is DC connected to ground, is provided at the deposition shield 76 at substantially the same position as the semiconductor wafer W, thereby preventing abnormal discharge.

An entire operation of the plasma etching apparatus having the above configuration is controlled by a controller 60. The controller 60 includes a process controller 61 having a CPU to control each component of the plasma etching apparatus, a user interface 62 and a storage unit 63.

The user interface 62 includes a keyboard for inputting commands, a display for displaying an operation status of the plasma etching apparatus or the like to allow a process manager to manage the plasma etching apparatus.

The storage unit 63 stores recipes including control programs (software) for implementing various processes in the plasma etching apparatus under control of the process controller 61, process condition data and the like. If necessary, as a certain recipe is retrieved from the storage unit 63 in accordance with an instruction inputted through the user interface 62 and executed in the process controller 61, a desired process is performed in the plasma etching apparatus under control of the process controller 61. Further, the recipes including control programs, process condition data and the like can be stored in and retrieved from a computer-readable storage medium such as a hard disk, a CD-ROM, a flexible disk and a semiconductor memory, or retrieved through an on-line connected via, for example, a dedicated line to another apparatus available all the time.

Next, steps for plasma etching a silicon nitride layer, a silicon oxide layer or the like formed on the semiconductor wafer W in the plasma etching apparatus having the above configuration will be described. First, the gate valve 75 is opened and, then, the semiconductor wafer W is loaded into the processing chamber 1 from the loading/unloading port 74 through a load-lock chamber (not shown) by using a transfer robot (not shown) to be mounted on the mounting table 2. Then, the transfer robot is retracted from the processing chamber 1 and the gate valve 75 is closed. Then, the processing chamber 1 is evacuated through the gas exhaust port 71 by using the vacuum pump of the gas exhaust unit 73.

After the processing chamber 1 is maintained to have a predetermined vacuum level, a specific processing gas (etching gas) is introduced into the processing chamber 1 from the processing gas supply source 15. When the processing chamber 1 is maintained at a predetermined pressure of, e.g., 3.99 Pa (30 mTorr), a high frequency power having a frequency of, e.g., 40 MHz is supplied to the mounting table 2 from the second RF power supply 10b. Further, a high frequency power having a frequency of, e.g., 13.56 MHz for attracting ions is supplied to the mounting table 2 from the first RF power supply 10a. In this case, a specific DC voltage is applied to the electrode 6a of the electrostatic chuck 6 from the DC power supply 12, so that the semiconductor wafer W is adsorbed to the electrostatic chuck 6 by a Coulomb force.

In this case, when a high frequency power is applied to the mounting table 2 serving as a lower electrode as described above, an electric field is formed between the shower head 16 serving as an upper electrode and the mounting table 2 serving as a lower electrode. Accordingly, discharge occurs in the processing space including the semiconductor wafer W, and a plasma of the processing gas is generated to thereby etch the silicon nitride layer, silicon oxide layer or the like formed on the semiconductor wafer W.

Further, when the etching process has been completed, supplies of the high frequency power and the processing gas are stopped and the semiconductor wafer W is unloaded from the processing chamber 1 in a sequence opposite to the above-described sequence.

Next, a plasma etching method in accordance with the embodiment of the present invention will be described with reference to FIG. 1. FIG. 1 illustrates an enlarged view showing main parts of the semiconductor wafer W serving as a substrate to be processed in accordance with the embodiment of the present invention. As shown in FIG. 1, an ArF resist layer 102 (having a thickness of, e.g., 270 nm) patterned to have specific lines and spaces, an ARC (Anti-Reflection Coating) layer 103 (having a thickness of, e.g., 30 nm) and an SiN (silicon nitride) layer 104 (having a thickness of, e.g., 200 nm) are formed sequentially from top to bottom on a surface of a silicon substrate 101 having a diameter of 300 nm.

The semiconductor wafer W having the above structure is accommodated in the processing chamber 1 of the apparatus shown in FIG. 2 and mounted on the mounting table 2. In the state shown in FIG. 1, the ARC layer 103 and the SiN layer 104 are etched by using the ArF resist layer 102 as a mask to thereby form a pattern having lines and spaces.

As an experimental example, plasma etching was conducted for 60 seconds under conditions in which a pressure is 3.99 Pa (30 mTorr); a frequency of high frequency power, 40 MHz (400 W)/13.56 MHz (500 W and 1000 W); temperatures (top/sidewall/mounting portion), 60/60/30° C.; and backside helium pressures (center/periphery), 2000/2000 Pa. Further, the pattern having lines and spaces included a dense pattern portion in which a ratio of a line width to a space width is 1/1 (line width/space width) and a sparse pattern portion in which a ratio of a line width to a space width is 1/10.

As a result, when a bias power having a frequency of 13.56 MHz was 0 W (reference example), an etching rate of the SiN layer 104 was 0, whereas when the a bias power was 500 W or 1000 W, an etching rate of SiN and selectivity (etching rate of SiN/etching rate of ArF resist) were determined as follows:

(Bias power=500 W)

Dense pattern portion of 1/1

Etching rate=115 nm/min

Selectivity=1.92

Sparse pattern portion of 1/10

Etching rate=89 nm/min

Selectivity=1.39

(Bias power=1000 W)

Dense pattern portion of 1/1

Etching rate=200 nm/min

Selectivity=1.82

Sparse pattern portion of 1/10

Etching rate=175 nm/min

Selectivity=1.75

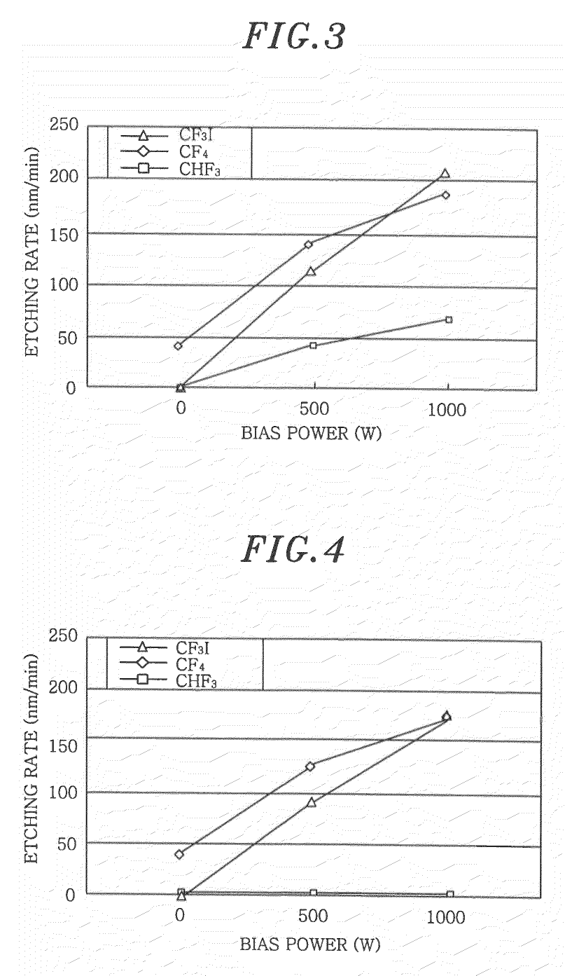

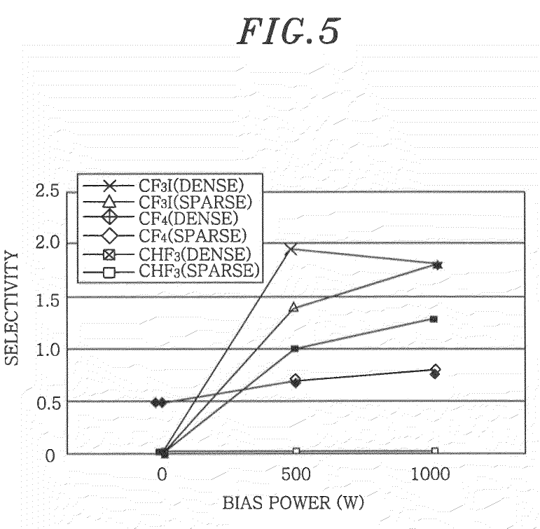

As a comparison example, etching was conducted while CF₄ or CHF₃ was used as an etching gas under the same conditions as the above-described experimental example and reference example. The results of the experimental example, comparison example and reference example are shown in graphs of FIGS. 3 to 5. FIG. 3 shows a relationship between an etching rate of SiN in a dense pattern portion of 1/1 and a bias power, and FIG. 4 shows a relationship between an etching rate of SiN in a sparse pattern portion of 1/10 and a bias power. FIG. 5 shows a relationship between selectivity of dense and sparse pattern portions and a bias power. As shown in these graphs, in the experimental example in which a CF₃I gas was used as an etching gas and a bias power having a frequency of 13.56 MHz was applied, it was possible to achieve an etching rate similar to that of a case using a CF₄ gas in both dense and sparse pattern portions, and a higher selectivity than that in any comparison example. Further, as shown in the graphs of FIGS. 3 to 5, when a bias power was 0 W, an etching rate also became zero. Accordingly, preferably, the bias power is equal to or larger than a certain value, preferably, 500 W. Further, it is preferable to use a bias power of 1000 W.

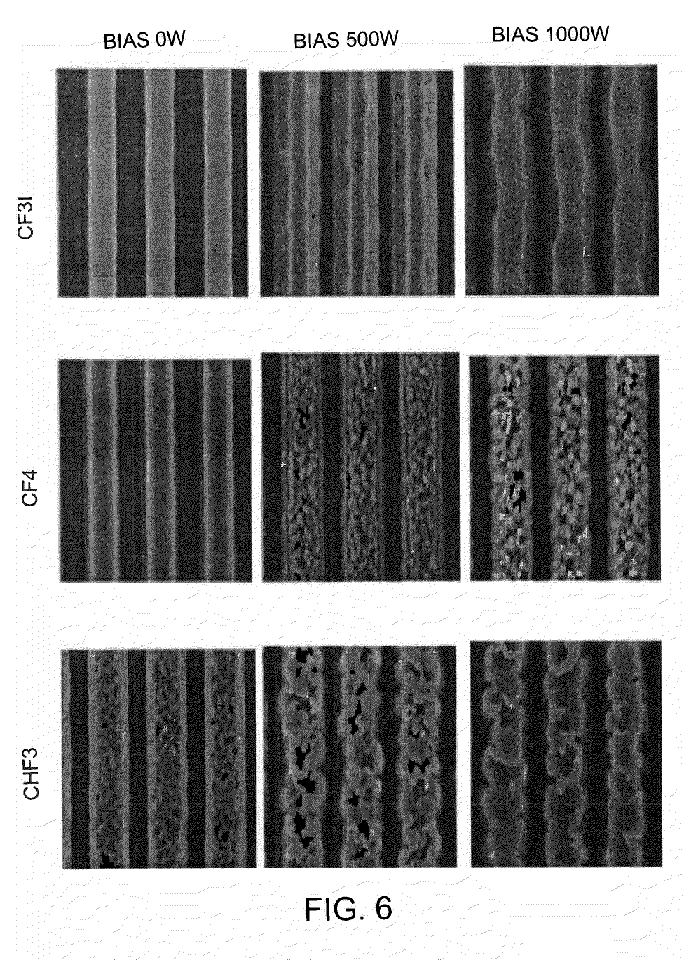

Further, FIG. 6 illustrates SEM enlarged photographs showing ArF resist states after etching in the experimental example, comparison example, and reference example. In FIG. 6, upper photographs were obtained when a CF₃I gas was used, middle photographs were obtained when a CF₄ gas was used, and lower photographs were obtained when a CHF₃ gas was used. Further, the photographs of FIG. 6 were obtained while bias powers of 0 W, 500 W and 1000 W were used sequentially from left to right. As shown in FIG. 6, in the experimental example using a CF₃I gas as an etching gas, in both a case using a bias power of 500 W and a case using a bias power of 1000 W, it was possible to effectively prevent roughness of the surface and sidewall of the ArF photoresist compared to the comparison example. Further, it was checked that it was possible to prevent generation of striation, LER and LWR.

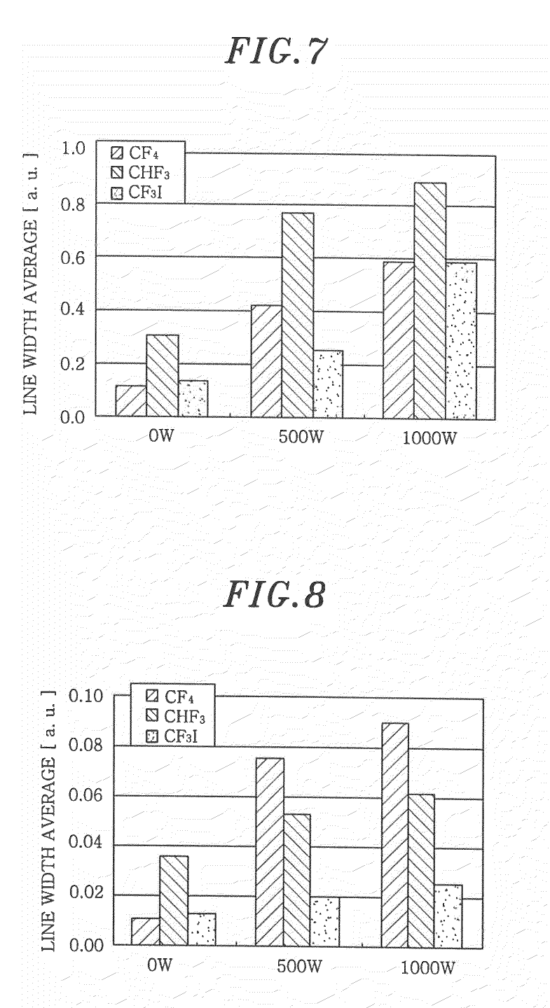

FIGS. 7 and 8 are bar graphs numerically showing LWR based on the SEM enlarged photographs. That is, line edges of the ArF resist were detected from the SEM photographs (estimated from line profiles of secondary electrons), and line widths were measured along a line at equal intervals. Then, the measured data were Fourier transformed to be compared in frequency ranges. Further, line widths were measured at 256 points at a measurement distance of 2.5 nm over a vertical measurement length of 640 nm. In this case, although SEM estimated measurement conditions include a measurement length of 2000 nm, a measurement distance of 10 nm and 200 measurement points, the measurement was performed under the above-mentioned conditions for detailed analysis of high frequency components.

FIG. 7 shows measurement results in a low frequency (long wavelength) range, and FIG. 8 shows measurement results in a high frequency (short wavelength) range. Further, in each bar graph, left, middle and right bars represent a case using a CF₄ gas, a case using a CHF₃ gas and a case using a CF₃I gas, respectively. As shown in these graphs, in the low frequency range, similar LWR levels were determined in both the case using a CF₃I gas and the case using a CF₄ gas, and in the high frequency range, the LWR was apparently suppressed in the case using a CF₃I gas compared to the case using a CF₄ gas and the case using a CHF₃ gas.

Further, although etching of a silicon nitride (SiN) layer is described in the above embodiment, the present invention may be applied to etching of a silicon oxide (SiO₂) layer in the same way. Further, although a single gas of a CF₃I gas is used as an etching gas in the above embodiment, a gaseous mixture containing a CF₃I gas and the like may be used. For example, in a case using a gaseous mixture containing a CHF₃ gas, a CF₄ gas and a CF₃I gas, a CF₃I gas is added to the gaseous mixture such that a ratio of a CF₃I gas flow rate to a total gas flow rate of a PFC gas is at least 1/3. For instance, when CHF₃ gas/CF₄ gas/CF₃I gas was 120/120/120 sccm, it was checked that generation of striation, LER and LWR was effectively suppressed.

As described above, in accordance with the embodiment of the present invention, it is possible to suppress roughness of a surface and sidewall of the ArF photoresist in highly anisotropic plasma etching having application of a high bias voltage and also possible to form a desired pattern with good precision by suppressing generation of striation, LER and LWR. Further, the present invention may be modified without being limited to the above-described embodiment. For example, the plasma etching apparatus may employ various plasma etching apparatuses such as an upper-and-lower plate dual frequency application type plasma etching apparatus or a lower plate single frequency application type plasma etching apparatus without being limited to a parallel plate type and lower plate dual frequency application type plasma etching apparatus shown in FIG. 2.

While the invention has been shown and described with respect to the embodiments, it will be understood by those skilled in the art that various changes and modifications may be made without departing from the scope of the invention as defined in the following claims.

What is claimed is:

1. A plasma etching method comprising:
etching an etching target layer formed on a substrate to be processed by a plasma of a processing gas by using an ArF photoresist as a mask,
wherein the etching target layer is a silicon nitride layer or silicon oxide layer,
the processing gas contains at least a CF₃I gas, and
a high frequency power having a frequency of 13.56 MHz or less is applied to a lower electrode mounting the substrate thereon.

2. The plasma etching method of claim 1, wherein the high frequency power, having a frequency of 13.56 MHz or less and applied to the lower electrode, is equal to or larger than 500 W.

3. The plasma etching method of claim 1, wherein an etching pattern having lines and spaces is formed on the etching target layer, and the etching pattern includes a dense pattern portion in which a ratio of a line width to a space width is 1/1 (line width/space width) and a sparse pattern portion in which a ratio of a line width to a space width is 1/10 or less.

4. The plasma etching method of claim 1, wherein a second high frequency power having a frequency of 27 MHz or more in addition to the high frequency power having a frequency of 13.56 MHz or less is applied to the lower electrode.

5. A computer-readable storage medium for storing a control program executed on a computer, the control program controlling a plasma etching apparatus to perform the plasma etching method described in claim 1.
